(19) United States
(12) Patent Application Publication
(10) Pub. No.: US 2023/0246127 A1
(43) Pub. Date: Aug. 3, 2023

(54) DISPLAY DEVICE AND METHOD OF FABRICATING THE SAME

(71) Applicant: Samsung Display Co., LTD., Yongin-si (KR)

(72) Inventors: Hoo Keun PARK, Cheongju-si (KR); Sang Jo KIM, Daejeon (KR); Su Jeong KIM, Hwaseong-si (KR); Byung Ju LEE, Seoul (KR)

(73) Assignee: Samsung Display Co., LTD., Yongin-si (KR)

(21) Appl. No.: 17/944,511

(22) Filed: Sep. 14, 2022

(30) Foreign Application Priority Data
Jan. 21, 2022 (KR) 10-2022-0009342

(51) Int. Cl. H01L 33/18; H01L 27/15; H01L 33/32; H01L 33/00

(52) U.S. Cl. CPC H01L 33/18; H01L 27/156; H01L 33/007; H01L 33/0093; H01L 33/325

(57) ABSTRACT

A display device includes first banks spaced apart from one another and disposed on a substrate, a first electrode and a second electrode disposed on the respective first banks to cover the respective first banks, the first electrode and the second electrode being spaced apart from each other, and a light-emitting element disposed between the first electrode and the second electrode. The light-emitting element includes an active layer, a first semiconductor layer, and a second semiconductor layer disposed between the active layer and the first electrode. The first semiconductor layer includes a main semiconductor layer and a nanoporous layer disposed in the main semiconductor layer.

### CROSS REFERENCE TO RELATED APPLICATION(S)

This application claims priority to and benefits of Korean Patent Application No. 10-2022-0009342 under 35 U.S.C. §119, filed on Jan. 21, 2022, in the Korean Intellectual Property Office (KIPO), entire contents of which are incorporated herein by reference.

### BACKGROUND

### 1. Technical Field

The disclosure relates to a display device and a method of fabricating the same.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, and an organic light-emitting display device. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel.

### SUMMARY

Aspects of the disclosure provide a display device that can improve the issue of n contact loss.

Aspects of the disclosure also provide a method of fabricating a display device that can improve the issue of n contact loss.

It should be noted that objects of the disclosure are not limited to the above-mentioned object; and other objects of the disclosure will be apparent to those skilled in the art from the following descriptions.

According to embodiments of the disclosure, it is possible to improve the issue of n contact loss.

It should be noted that effects of the disclosure are not limited to those described above and other effects of the disclosure will be apparent to those skilled in the art from the following descriptions.

According to an embodiment of the disclosure, a display device may include first banks spaced apart from one another and disposed on a substrate; a first electrode and a second electrode disposed on the respective first banks to cover the respective first banks, the first electrode and the second electrode being spaced apart from each other; and a light-emitting element disposed between the first electrode and the second electrode. The light-emitting element may include an active layer, a first semiconductor layer, and a second semiconductor layer disposed between the active layer and the first electrode. The first semiconductor layer may include a main semiconductor layer, and a nanoporous layer disposed in the main semiconductor layer.

In an embodiment, the main semiconductor layer may directly contact an outer surface of the nanoporous layer.

In an embodiment, the main semiconductor layer may include GaN doped with n-type Si.

In an embodiment, the second semiconductor layer may include GaN doped with p-type Si.

In an embodiment, the first semiconductor layer may further include a one-side sub-semiconductor layer between the nanoporous layer and the main semiconductor layer.

In an embodiment, the one-side sub-semiconductor layer may include GaN doped with n-type Si.

In an embodiment, an n-type Si doping concentration of the main semiconductor layer may be greater than an n-type Si doping concentration of the one-side sub-semiconductor layer.

In an embodiment, an end of the light-emitting element may be aligned with an end of the main semiconductor layer and an end of the nanoporous layer.

In an embodiment, the first semiconductor layer may further include an opposite-side sub-semiconductor layer spaced apart from the one-side sub-semiconductor layer with the nanoporous layer therebetween.

In an embodiment, the opposite-side sub-semiconductor layer may include GaN doped with n-type Si.

In an embodiment, the n-type Si doping concentration of the main semiconductor layer may be greater than an n-type Si doping concentration of the opposite-side sub-semiconductor layer.

In an embodiment, the light-emitting element may further include an insulating layer covering an outer surface of the active layer, an outer surface of the main semiconductor layer, and an outer surface of the second semiconductor layer.

In an embodiment, a thickness of the active layer may be smaller than a thickness of the main semiconductor layer in a lateral direction, and the light-emitting element may further include an insulating layer disposed between the main semiconductor layer and the second semiconductor layer. In an embodiment, the insulating layer may contact an outer surface of the active layer.

In an embodiment, a thickness of the active layer may be smaller than a thickness of the main semiconductor layer in a lateral direction. The light-emitting element may further include a first insulating layer disposed on an outer surface of the active layer, and a second insulating layer covering an outer surface of the active layer, an outer surface of the main semiconductor layer, and an outer surface of the second semiconductor layer.

According to an embodiment of the disclosure, a method of fabricating a display device may include: forming an undoped semiconductor layer on a substrate; forming an intermediate semiconductor layer including GaN doped with n-type Si on the undoped semiconductor layer; forming a first sub-semiconductor layer including GaN doped with n-type Si on the intermediate semiconductor layer; forming a nanoporous layer by electrochemically etching the intermediate semiconductor layer; etching the nanoporous layer and the first sub-semiconductor layer after placing a hard mask on the first sub-semiconductor layer; growing a main semiconductor layer on a side surface of the nanoporous layer and a side surface of the first sub-semiconductor layer; removing the hard mask; re-growing the main semiconductor layer; forming an active layer on the main semiconductor layer; forming a second semiconductor layer including GaN doped with p-type Si on the active layer; forming an electrode layer on the second semiconductor layer; and etching the electrode layer, the second semiconductor layer, the active layer, and the main semiconductor layer using a mask on the electrode layer.

In an embodiment, the main semiconductor layer may include GaN doped with n-type Si, and an n-type Si doping concentration of the main semiconductor layer is greater than an n-type Si doping concentration of the first sub-semiconductor layer.

In an embodiment, after the etching of the electrode layer, the second semiconductor layer, the active layer and the main semiconductor layer using the mask on the electrode layer, the method of fabricating a display device further includes forming an insulating layer covering a side surface of the active layer, a side surface of the main semiconductor layer, and a side surface of the second semiconductor layer.

In an embodiment, the method of fabricating a display device may further include forming a second sub-semiconductor layer including GaN doped with n-type Si on the undoped semiconductor layer, between the forming of the undoped semiconductor layer on the substrate and the forming of the intermediate semiconductor layer including GaN doped with n-type Si on the undoped semiconductor layer. The etching of the nanoporous layer and the first sub-semiconductor layer after placing a hard mask on the first sub-semiconductor layer may include etching the second sub-semiconductor layer, and the main semiconductor layer may be further formed on a side surface of the second sub-semiconductor layer.

According to another embodiment of the disclosure, a method of fabricating a display device may include: forming an undoped semiconductor layer on a substrate; forming an intermediate semiconductor layer including GaN doped with n-type Si on the undoped semiconductor layer; forming a first sub-semiconductor layer including GaN doped with n-type Si on the intermediate semiconductor layer; forming a nanoporous layer by electrochemically etching the intermediate semiconductor layer; etching the nanoporous layer and the first sub-semiconductor layer after disposing a first hard mask on the first sub-semiconductor layer; growing a main semiconductor layer on a side surface of the nanoporous layer and a side surface of the first sub-semiconductor layer; removing the first hard mask; re-growing the main semiconductor layer; disposing a second hard mask comprising a through hole on the re-grown main semiconductor layer; forming an active layer on the re-grown main semiconductor layer in the through hole of the second hard mask; forming a second semiconductor layer including GaN doped with p-type Si on the second hard mask and the active layer; forming an electrode layer on the second semiconductor layer; and etching the electrode layer, the second hard mask, the second semiconductor layer, and the main semiconductor layer using a mask on the electrode layer.

### BRIEF DESCRIPTION OF THE DRAWINGS

The above and other aspects and features of the disclosure will become more apparent by describing in detail embodiments thereof with reference to the attached drawings.

FIG. 1 is a plan view showing a display device according to an embodiment of the disclosure.

FIG. 2 is an enlarged schematic cross-sectional view taken along line I - I′ of FIG. 1.

FIG. 3 is a plan view showing a single pixel of a display device according to an embodiment of the disclosure.

FIG. 4 is a schematic cross-sectional view taken along line II - II′ of FIG. 3.

FIG. 5 is an enlarged view of area A of FIG. 4.

FIGS. 6 to 16 are schematic cross-sectional views showing processing steps of a method of fabricating a display device according to an embodiment of the disclosure.

FIG. 17 is a schematic cross-sectional view showing a light-emitting element in a display device according to another embodiment.

FIG. 18 is a schematic cross-sectional view showing a light-emitting element in a display device according to yet another embodiment.

FIGS. 19 to 27 are schematic cross-sectional views showing processing steps of a method of fabricating a display device according to yet another embodiment of the disclosure.

FIG. 28 is a schematic cross-sectional view showing a light-emitting element in a display device according to yet another embodiment.

FIG. 29 is a schematic cross-sectional view showing a light-emitting element in a display device according to yet another embodiment.

FIG. 30 is a schematic cross-sectional view showing a light-emitting element in a display device according to yet another embodiment.

FIG. 31 is a schematic cross-sectional view of a display device according to yet another embodiment of the disclosure.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, embodiments are provided so that this disclosure will be thorough and complete, and will filly convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Other expressions that explain the relationship between elements, such as “between,” “directly between,” “adjacent to,” or “directly adjacent to,” should be construed in the same way. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Features of each of embodiments of the disclosure may be partially or entirely combined with each other and may technically variously interwork with each other, and respective embodiments may be implemented independently of each other or may be implemented together in association with each other.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings.

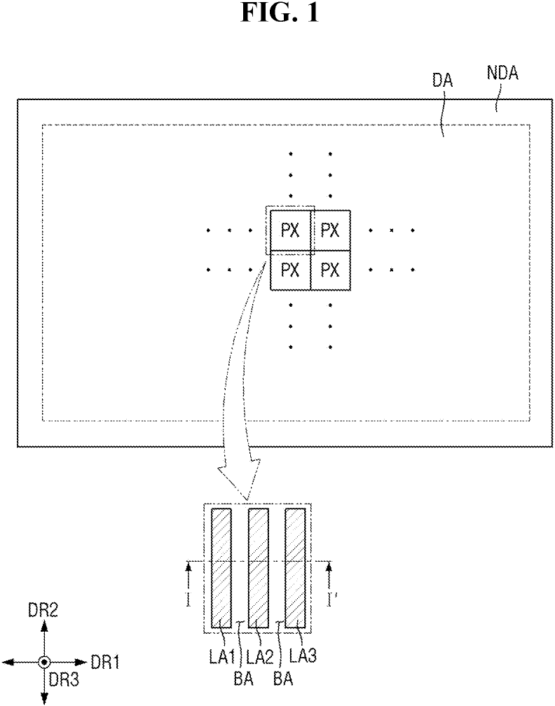

FIG. 1 is a plan view showing a display device according to an embodiment of the disclosure.

Referring to FIG. 1, a display device according to an embodiment of the disclosure may have a rectangular shape in a plan view. It is, however, to be understood that the disclosure is not limited thereto. The shape of the display device may be a square, a circle, an ellipse, or other polygons in a plan view. In the following description, the display device has a rectangular shape in a plan view.

The display device may include a display panel that provides a display screen. Examples of the display panel may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an embodiment of the display panel 10, but the disclosure is not limited thereto. Any other display panel may be employed as long as the technical idea of the disclosure may be equally applied.

The display device may include a display area DA and a non-display area NDA. The display area DA may include multiple pixels PX to display images. The pixels PX may be arranged in a matrix pattern. The non-display area NDA may be disposed around the display area DA to surround the display area DA, and may display no image. The non-display area NDA may completely surround the display area DA in a plan view. The display area DPA may be referred to as an active area, and the non-display area NDA may also be referred to as an inactive area. The display area DA may generally occupy the center of the display device.

The non-display area NDA may be located on one side and the opposite side in a first direction DR1, and one side and the opposite side in a second direction DR2. It is, however, to be understood that the disclosure is not limited thereto. The non-display area NDA may be located only on one side and the opposite side in the first direction DR1, or only on one side and the opposite side in the second direction DR2. Lines or circuit drivers included in the display device may be disposed or external devices may be mounted in the non-display area NDA.

Referring to the enlarged view of FIG. 1, each of the pixels PX of the display device may include light-emitting areas LA1, LA2 and LA3 defined by a pixel-defining layer, and may emit light having a predetermined (or selectable) peak wavelength through the light-emitting areas LA1, LA2 and LA3. For example, the display area DA of each of the display devices may include first to third light-emitting areas LA1, LA2 and LA3. In each of the first to third light-emitting areas LA1, LA2 and LA3, light generated by light-emitting elements of the display devices exits out of the display devices.

The first to third light-emitting areas LA1, LA2 and LA3 may emit light having predetermined (or selectable) peak wavelengths to the outside of the display devices. The first light-emitting area LA1 may emit light of a first color, the second light-emitting area LA2 may emit light of a second color, and the third light-emitting area LA3 may emit light of a third color. For example, the light of the first color may be red light having a peak wavelength in the range of about 610 nm to about 650 nm, the light of the second color may be green light having a peak wavelength in the range of about 510 nm to about 550 nm, and the light of the third color may be blue light having a peak wavelength in the range of about 440 nm to about 480 nm. It is, however, to be understood that the disclosure is not limited thereto.

The display area DA of the display device may include light-blocking areas BA located between the adjacent ones of the light-emitting areas LA1, LA2 and LA3. For example, the light-blocking areas between the light-emitting areas may surround the first light-emitting area LA1 to the third light-emitting area LA3.

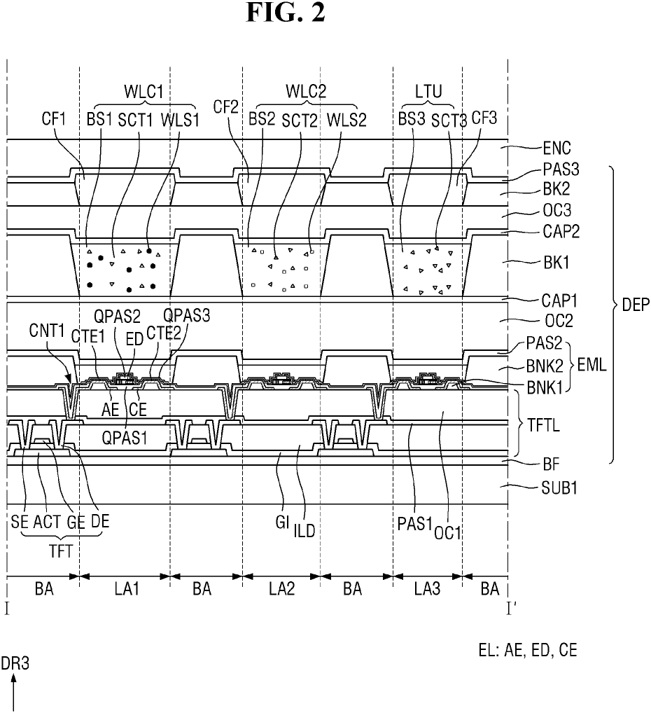

FIG. 2 is an enlarged schematic cross-sectional view taken along line I - I′ of FIG. 1.

Referring to FIG. 2, the display device may include a first substrate SUB1 disposed across the display area DA and the non-display area NDA, a display element layer DEP on the first substrate SUB1 disposed in the display area DA, and an encapsulation member ENC disposed across the display area DA and the non-display area NDA to encapsulate the display element layer DEP.

The first substrate SUB1 may be made of an insulating material such as polymer resin. The insulating material may include, for example, polyimide (PI).

The display element layer DEP may include a buffer layer BF, a thin-film transistor layer TFTL, an emission layer EML, a second planarization layer OC2, a first capping layer CAP1, a first light-blocking member BK1, a first wavelength-converting part WLC1, a second wavelength-converting part WLC2, a light-transmitting part LTU, a second capping layer CAP2, a third planarization layer OC3, a second light-blocking member BK2, first to third color filters CF1, CF2 and CF3, and a third passivation layer PAS3.

The buffer layer BF may be disposed on the substrate 100. The buffer layer BF may be formed of an inorganic film that can prevent the permeation of air or moisture.

The thin-film transistor layer TFTL may include a thin-film transistor TFT, a gate insulating layer GI, an interlayer dielectric film ILD, a first passivation layer PAS1, and a first planarization layer OC1.

The thin-film transistor TFT may be disposed on the buffer layer BF, and may form a pixel circuit of each of the pixels.

The semiconductor layer ACT may be disposed on the buffer layer BF. The semiconductor layer ACT may overlap the gate electrode GE, the source electrode SE, and the drain electrode DE. The semiconductor layer ACT may directly contact the source electrode SE and the drain electrode DE, and may face the gate electrode GE with the gate insulating layer GI therebetween.

The gate electrode GE may be disposed on the gate insulating layer GI. The gate electrode GE may overlap the semiconductor layer ACT with the gate insulating layer GI interposed therebetween.

The source electrode SE and the drain electrode DE may be disposed on the interlayer dielectric layer ILD such that they are spaced apart from each other. The source electrode SE may contact an end of the semiconductor layer ACT through a contact hole formed in the gate insulating layer GI and the interlayer dielectric layer ILD. The drain electrode DE may contact another end of the semiconductor layer ACT through a contact hole formed in the gate insulating layer GI and the interlayer dielectric layer ILD. The drain electrode DE may be electrically connected to a first electrode AE of a light-emitting element EL through a contact hole formed in the first passivation layer PAS1 and the first planarization layer OC1.

The gate insulating layer GI may be disposed on the semiconductor layer ACT. For example, the gate insulating layer GI may be disposed on the semiconductor layer ACT and the buffer layer BF, and may insulate the semiconductor layer ACT from the gate electrode GE. The gate insulating layer GI may include a contact hole through which the source electrode SE penetrates and a contact hole through which the drain electrode DE penetrates.

The interlayer dielectric layer ILD may be disposed over the gate electrode GE. For example, the interlayer dielectric layer ILD may include a contact hole through which the source electrode SE penetrates, and a contact hole through which the drain electrode DE penetrates.

The first passivation layer PAS1 may be disposed above the thin-film transistor TFT to protect the thin-film transistor TFT. For example, the first passivation layer PAS1 may include a contact hole through which the first electrode AE penetrates.

The first planarization layer OC1 may be disposed on the first passivation layer PAS1 to provide a flat surface over the thin-film transistor TFT. For example, the first planarization layer OC1 may include a contact hole through which the first electrode AE of the light-emitting element EL penetrates.

The emission layer EML may include a light-emitting element EL, a first bank BNK1, a second bank BNK2, a first element insulating layer QPAS1, and a second passivation layer PAS2.

The light-emitting element EL may be disposed on the thin-film transistor TFT. The light-emitting element EL may include a first electrode AE, a second electrode CE, and a light-emitting diode ED.

The first electrode AE may be disposed on the first planarization layer OC1. For example, the first electrode AE may be disposed over the first bank BNK1 disposed on the first planarization layer OC1 to cover the first bank BNK1. The first electrode AE may be disposed to overlap one of the first to third light-emitting areas LA1, LA2 and LA3 defined by the second bank BNK2. The first electrode AE may be electrically connected to the drain electrode DE of the thin-film transistor TFT.

The second electrode CE may be disposed on the first planarization layer OC1. For example, the second electrode CE may be disposed over the first bank BNK1 disposed on the first planarization layer OC1 to cover the first bank BNK1. The second electrode CE may be disposed to overlap one of the first to third light-emitting areas LA1, LA2 and LA3 defined by the second bank BNK2. For example, the second electrode CE may receive a common voltage applied to all pixels.

The first element insulating layer QPAS1 may cover a part of the first electrode AE and a part of the second electrode CE adjacent to each other and may insulate the first and second electrodes AE and CE from each other.

The light-emitting diode ED may be disposed between the first electrode AE and the second electrode CE above the first planarization layer OC1. The light-emitting diode ED may be disposed on the first element insulating layer QPAS1. An end of the light-emitting diode ED may be electrically connected to the first electrode AE, and another end of the light-emitting diode ED may be electrically connected to the second electrode CE. For example, the multiple light-emitting diodes ED may include active layers having the same material so that they may emit light of the same wavelength or light of the same color. The lights emitted from the first to third light-emitting areas LA1, LA2 and LA3, respectively, may have the same color. For example, the light-emitting diodes ED may emit light of the third color or blue light having a peak wavelength in the range of about 440 nm to about 480 nm.

The second bank BNK2 may be disposed on the first planarization layer OC1 to define first to third light-emitting areas LA1, LA, and LA3. For example, the second bank BNK2 may surround each of the first to third light-emitting areas LA1, LA2 and LA3. It is, however, to be understood that the disclosure is not limited thereto. The second bank BNK2 may be disposed in each of the light-blocking areas BA.

The second passivation layer PAS2 may be disposed on the light-emitting elements EL and the second bank BNK2. The second passivation layer PAS2 may cover the light-emitting elements EL to protect the light-emitting elements EL.

The display device may further include the second planarization layer OC2, the first capping layer CAP1, the first light-blocking member BK1, the first wavelength converting part WLC1, the second wavelength converting part WLC2, the light-transmitting part LTU, the second capping layer CAP2, the third planarization layer OC3, the second light-blocking member BK2, the first to third color filters CF1, CF2 and CF3, the third passivation layer PAS3, and the encapsulation member ENC.

The second planarization layer OC2 may be disposed on the emission layer EML to provide a flat surface over the emission layer EML. The second planarization layer OC2 may include an organic material.

The first capping layer CAP1 may be disposed on the second planarization layer OC2. The first capping layer CAP1 may seal the lower surfaces of the first and second wavelength converting parts WLC1 and WLC2 and the light-transmitting part LTU. The first capping layer CAP1 may include an inorganic material.

The first light-blocking member BK1 may be disposed on the first capping layer CAP1 in the light-blocking area BA. The first light-blocking member BK1 may overlap the second bank BNK2 in the thickness direction. The first light-blocking member BK1 may block the transmission of light.

The first light-blocking member BK1 may include an organic light-blocking material and a liquid repellent component.

Since the first light-blocking member BK1 includes a liquid repellent component, the first and second wavelength converting parts WLC1 and WLC2 and the light-transmitting part LTU may be separated so that they can correspond to the respective light-emitting areas LA.

The first wavelength converting part WLC1 may be disposed in the first emission area LA1 on the first capping layer CAP1. The first wavelength converting part WLC1 may be surrounded by the first light-blocking member BK1. The first wavelength-converting part WLC1 may include a first base resin BS1, first scatterers SCT1, and first wavelength shifters WLS1.

The first base resin BS1 may include a material having a relatively high light transmittance. The first base resin BS1 may be made of a transparent organic material. For example, the first base resin BS1 may include at least one organic material such as epoxy resin, acrylic resin, cardo resin, and imide resin.

The first scatterers SCT1 may have a refractive index different from that of the first base resin BS1 and may form an optical interface with the first base resin BS1.

The first wavelength shifters WLS1 may convert or shift the peak wavelength of the incident light to a first peak wavelength. For example, the first wavelength shifters WLS1 may convert blue light provided from the display device into red light having a single peak wavelength in the range of about 610 nm to about 650 nm, and may output the light. The first wavelength shifters WLS1 may be quantum dots, quantum rods, or phosphor. The quantum dots may be particulate matter that emits a color as electrons transition from the conduction band to the valence band.

The light output from the first wavelength shifters WLS1 may have a full width of half maximum (FWHM) of the emission wavelength spectrum of about 45 nm or less, about 40 nm or less, or about 30 nm or less. Accordingly, the color purity and color gamut of the colors displayed by the display device may be further improved.

A part of the blue light emitted from the emission layer EML may pass through the first wavelength-converting part WLC1 without being converted into red light by the first wavelength shifters WLS1. In case that such blue light is incident on the first color filter CF1, it may be blocked by the first color filter CF1. On the other hand, red light converted by the first wavelength-converting part WLC1 may pass through the first color filter CF1 to exit to the outside. Accordingly, the first light-emitting area LA1 may emit red light.

The second wavelength-converting part WLC2 may be disposed in the second light-emitting area LA2 on the first capping layer CAP1. The second wavelength-converting part WLC2 may be surrounded by the first light-blocking member BK1. The second wavelength-converting part WLC2 may include a second base resin BS2, second scatterers SCT2, and second wavelength shifters WLS2.

The second base resin BS2 may include a material having a relatively high light transmittance. The second base resin BS2 may be made of a transparent organic material.

The second scatterers SCT2 may have a refractive index different from that of the second base resin BS2 and may form an optical interface with the second base resin BS2. For example, the second scatterers SCT2 may include a light scattering material or light scattering particles that scatter at least a part of transmitted light.

The second wavelength shifters WLS2 may convert or shift the peak wavelength of the incident light to a second peak wavelength that is different from the first peak wavelength of the first wavelength shifters WLS1. For example, the second wavelength shifters WLS2 may convert blue light provided from the display device into green light having a single peak wavelength in the range of about 510 nm to about 550 nm, and may output the light. The second wavelength shifters WLS2 may be quantum dots, quantum rods, or phosphor. The second wavelength shifters WLS2 may include the above-listed materials of the first wavelength shifters WLS1.

The light output from the second wavelength shifters WLS2 may have a full width of half maximum (FWHM) of the emission wavelength spectrum of about 45 nm or less, about 40 nm or less, or about 30 nm or less. Accordingly, the color purity and color gamut of the colors displayed by the display device may be further improved.

A part of the blue light emitted from the emission layer EML may pass through the second wavelength-converting part WLC1 without being converted into green light by the second wavelength shifters WLS2. In case that such blue light is incident on the second color filter CF2, it may be blocked by the second color filter CF2. On the other hand, green light converted by the second wavelength-converting part WLC2 may pass through the second color filter CF2 to exit to the outside. Accordingly, the second light-emitting area LA2 may emit green light.

The light-transmitting part LTU may be disposed in the third light-emitting area LA3 on the first capping layer CAP1. The light-transmitting part LTU may be surrounded by the first light-blocking member BK1. The light-transmitting part LTU may transmit the incident light without converting its peak wavelength. The light-transmitting part LTU may include a third base resin BS3 and third scatterers SCT3.

The third base resin BS3 may include a material having a relatively high light transmittance. The third base resin BS3 may be made of a transparent organic material.

The third scatterers SCT3 may have a refractive index different from that of the third base resin BS3 and may form an optical interface with the third base resin BS3. For example, the third scatterers SCT3 may include a light scattering material or light scattering particles that scatter at least a part of transmitted light.

The first and second wavelength converting parts WLC1 and WLC2 and the light-transmitting part LTU may be disposed on the emission layer EML with the second planarization layer OC2 and the first capping layer CAP1 interposed therebetween. Therefore, the display device may not require a separate substrate for the first and second wavelength converting parts WLC1 and WLC2 and the light-transmitting part LTU.

The second capping layer CAP2 may cover the first and second wavelength converting parts WLC1 and WLC2, the light-transmitting part LTU, and the first light-blocking member BK1.

The third planarization layer OC3 may be disposed on the second capping layer CAP2 to provide flat top surfaces for the first and second wavelength converting parts WLC1 and WLC2 and the light-transmitting part LTU. The third planarization layer OC3 may include an organic material.

The second light-blocking member BK2 may be disposed on the third planarization layer OC3 in the light-blocking area BA. The second light-blocking member BK2 may overlap the first light-blocking member BK1 or the second bank BNK2 in the thickness direction. The second light-blocking member BK2 may block the transmission of light.

The first color filter CF1 may be disposed in the first light-emitting area LA1 on the third planarization layer OC3. The first color filter CF1 may be surrounded by the second light-blocking member BK2. The first color filter CF1 may overlap the first wavelength-converting part WLC1 in the thickness direction. The first color filter CF1 may selectively transmit light of the first color (e.g., red light) and may block and absorb light of the second color (e.g., green light) and light of the third color (e.g., blue light).

The second color filter CF2 may be disposed on the third planarization layer OC3 in the second light-emitting area LA2. The second color filter CF2 may be surrounded by the second light-blocking member BK2. The second color filter CF2 may overlap the second wavelength-converting part WLC2 in the thickness direction. The second color filter CF2 may selectively transmit light of the second color (e.g., green light) and may block and absorb light of the first color (e.g., red light) and light of the third color (e.g., blue light).

The third color filter CF3 may be disposed in the third light-emitting area LA3 on the third planarization layer OC3. The third color filter CF3 may be surrounded by the second light-blocking member BK2. The third color filter CF3 may overlap the light-transmitting part LTU in the thickness direction. The third color filter CF3 may selectively transmit light of the third color (e.g., blue light) and may block and absorb light of the first color (e.g., red light) and light of the second color (e.g., green light).

The first to third color filters CF1, CF2 and CF3 may absorb a part of the light introduced from the outside of the display device to reduce reflection of external light. Accordingly, the first to third color filters CF1, CF2 and CF3 may prevent color distortion due to reflection of external light.

The third passivation layer PAS3 may cover the first to third color filters CF1, CF2 and CF3. The third passivation layer PAS3 may protect the first to third color filters CF1, CF2 and CF3.

The encapsulation member ENC may be disposed on the third passivation layer PAS3. For example, the encapsulation member ENC may include at least one inorganic layer to prevent permeation of oxygen or moisture. The encapsulation member ENC may also include at least one organic layer to protect the display device from foreign substances such as dust.

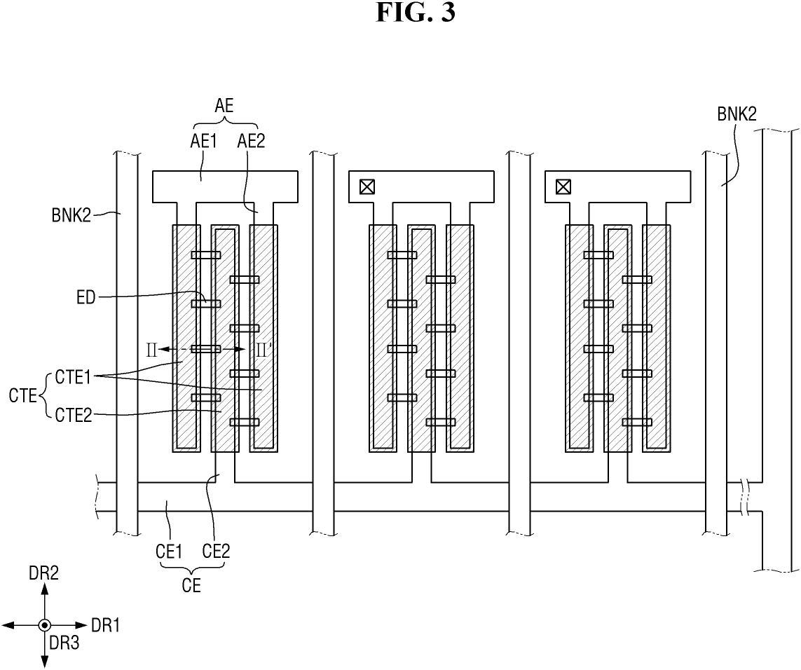

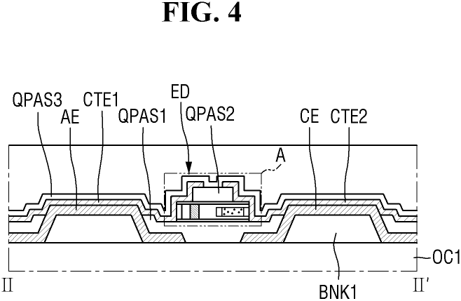

FIG. 3 is a plan view showing a single pixel of a display device according to an embodiment of the disclosure. FIG. 4 is a schematic cross-sectional view taken along line II -II′ of FIG. 3.

Referring to FIGS. 3 and 4 in conjunction with FIG. 2, each of the pixels may include first to third sub-pixels. The first to third sub-pixels may correspond to the first to third light-emitting areas LA1, LA2 and LA3, respectively. The light-emitting diodes ED of each of the first to third sub-pixels may emit light in the first to third light-emitting areas LA1, LA2 and LA3.

The first to third sub-pixels may emit light of the same color. For example, each of the first to third sub-pixels may include the light-emitting diodes ED of the same type, and may emit light of the third color or blue light. In another embodiment, the first sub-pixel may emit light of the first color or red light, the second sub-pixel may emit light of the second color or green light, and the third sub-pixel may emit light of the third color or blue light.

Each of the first to third sub-pixels may include first and second electrodes AE and CE, light-emitting diodes ED, multiple contact electrodes CTE, and multiple first banks BNK1.

The first and second electrodes AE and CE may be electrically connected to the light-emitting diodes ED and may receive a predetermined (or selectable) voltage, and the light-emitting diodes ED may emit light of a certain wavelength band. At least a part of the first and second electrodes AE and CE may form an electric field in the pixel, and the light-emitting diodes ED may be aligned by the electric field.

For example, the first electrode AE may be a pixel electrode disposed separately in each of the first to third sub-pixels, while the second electrode CE may be a common electrode commonly electrically connected to the first to third sub-pixels. One of the first electrode AE and the second electrode CE may be an anode electrode of the light-emitting diodes ED, while the other may be a cathode electrode of the light-emitting diodes ED.

The first electrode AE may include a first electrode stem AE1 extended in the first direction DR1, and at least one first electrode branch AE2 branching off from the first electrode stem AE1 and extended in the second direction DR2.

The first electrode stem AE1 of each of the first to third sub-pixels may be spaced apart from the first electrode stem AE1 of an adjacent sub-pixel, and the first electrode stems AE1 may be disposed on an imaginary extension line with the first electrode stem AE1 of the sub-pixel adjacent in the first direction DR1. The first electrode stems AE1 of the first to third sub-pixels may receive different signals, respectively, and may be driven individually.

The first electrode branch AE2 may branch off from the first electrode stem AE1 and may be extended in the second direction DR2. An end of the first electrode branch AE2 may be electrically connected to the first electrode stem AE1, while another end of the first electrode branch AE2 may be spaced apart from the second electrode stem CE1 opposed to the first electrode stem AE1.

The second electrode CE may include a second electrode stem CE1 extended in the first direction DR1, and a second electrode branch CE2 branching off from the second electrode stem CE1 and extended in the second direction DR2. The second electrode stem CE1 of each of the first to third sub-pixels may be electrically connected to the second electrode stem CE1 of an adjacent sub-pixel. The second electrode stem CE1 may be extended in the first direction DR1 to traverse the pixels. The second electrode stem CE1 may be electrically connected to a portion extended in a direction at the outer portion of the display area DA or in the non-display area NDA.

The second electrode branch CE2 may be spaced apart from and face the first electrode branch AE2. An end of the second electrode branch CE2 may be electrically connected to the second electrode stem CE1, while another end of the second electrode branch CE2 may be spaced apart from the first electrode stem AE1.

The first electrode AE may be electrically connected to the thin-film transistor layer TFTL of the display device through a first contact hole CNT1, and the second electrode CE may be electrically connected to the thin-film transistor layer TFTL of the display device through a second contact hole CNT2 (not shown). For example, the first contact hole CNT1 may be formed in each of the first electrode branches AE2, and the second contact hole CNT2 (not shown) may be formed in the second electrode stem CE1. It is, however, to be understood that the disclosure is not limited thereto.

The second banks BNK2 may be disposed at the boundary between the pixels. The first electrode branches AE2 may be spaced apart from one another with respect to the second banks BNK2. The second banks BNK2 may be extended in the second direction DR2 and may be disposed at the boundaries of the pixels SP arranged in the first direction DR1. The second banks BNK2 may be disposed at the boundaries of the pixels SP arranged in the second direction DR2 as well. The second banks BNK2 may define the boundaries of the pixels.

In case that an ink in which the light-emitting diodes ED are dispersed is sprayed during the process of fabricating the display device, the second banks BNK2 may prevent the ink from flowing over the boundaries of the pixels SP. The second banks BNK2 may separate the inks in which different light-emitting diodes ED are dispersed so that the inks are not mixed with each other.

The light-emitting diodes ED may be disposed between the first electrode AE and the second electrode CE. An end of the light-emitting diode ED may be electrically connected to the first electrode AE, and another end of the light-emitting diode ED may be electrically connected to the second electrode CE.

The light-emitting diodes ED may be spaced apart from one another and may be substantially aligned in parallel with one another. The spacing between the light-emitting diodes ED is not particularly limited herein.

The light-emitting diodes ED may include active layers having the same material so that they may emit light of the same wavelength range or light of the same color. The first to third sub-pixels may emit light of the same color. For example, the light-emitting diodes ED may emit light of the third color or blue light having a peak wavelength in the range of about 440 nm to about 480 nm.

The contact electrodes CTE may include first and second contact electrodes CTE1 and CTE2. The first contact electrode CTE1 may cover the first electrode branch AE2 and parts of the light-emitting diodes ED, and may electrically connect the first electrode branch AE2 with the light-emitting diodes ED. The second contact electrode CTE2 may cover the second electrode branch CE2 and other parts of the light emitting diodes ED, and may electrically connect the second electrode branch CE2 and the light emitting diodes ED.

The first contact electrode CTE1 may be disposed on the first electrode branch AE2 and extended in the second direction DR2. The first contact electrode CTE1 may contact first ends of the light-emitting diodes ED. The light-emitting diodes ED may be electrically connected to the first electrode AE through the first contact electrode CTE1.

The second contact electrode CTE2 may be disposed on the second electrode branch CE2 and extended in the second direction DR2. The second contact electrode CTE2 may be spaced apart from the first contact electrode CTE1 in the first direction DR1. The second contact electrode CTE2 may contact second ends of the light-emitting diodes ED. The light-emitting diodes ED may be electrically connected to the second electrode CE through the second contact electrode CTE2.

The emission layer EML of the display device may be disposed on the thin-film transistor layer TFTL, and may include first to third element insulating layers QPAS1, QPAS2 and QPAS3.

Multiple first banks BNK1 may be disposed in the first to third light-emitting areas LA1, LA2 and LA3, respectively. Each of the first banks BNK1 may be associated with the first electrode AE or the second electrode CE. Each of the first and second electrodes AE and CE may be disposed on the respective first bank BNK1. For example, the multiple first banks BNK1 may be disposed on the first planarization layer OC1, and the side surfaces of each of the first banks BNK1 may be inclined from the first planarization layer OC1. The inclined surfaces of the first banks BNK1 may reflect light emitted from the light-emitting diodes ED.

The first electrode stem AE1 may include the first contact hole CNT1 penetrating through the first planarization layer OC1. The first electrode stem AE1 may be electrically connected to the thin-film transistor TFT through the first contact hole CNT1.

The second electrode stem CE1 may be extended in the first direction DR1 and may be disposed also in a non-light-emitting area where the light-emitting diodes ED are not disposed. The second electrode branch CE2 may include the second contact hole CNT2 (not shown) penetrating through the first planarization layer OC1. The second electrode stem CE1 may be electrically connected to a power electrode through the second contact hole CNT2 (not shown). The second electrode CE may receive a predetermined (or selectable) electric signal from the power electrode.

The first and second electrodes AE and CE may include a transparent conductive material. The first and second electrodes AE and CE may include a conductive material with high reflectivity. The first and second electrodes AE and CE may be made up of a stack of one or more transparent conductive materials and one or more metals having high reflectivity or a single layer including them.

The first element insulating layer QPAS1 may be disposed on the first planarization layer OC1, the first electrode AE, and the second electrode CE. The first element insulating layer QPAS1 may partially cover each of the first and second electrodes AE and CE.

The first element insulating layer QPAS1 may protect the first and second electrodes AE and CE and may insulate the first and second electrodes AE and CE from each other. The first element insulating layer QPAS1 may prevent the light-emitting diodes ED directly contacting other elements and being damaged by them.

The light-emitting diodes ED may be disposed on the first element insulating layer QPAS1 between the first electrode AE and the second electrode CE. One ends of the light-emitting diodes ED may be electrically connected to the first electrode AE, and the second ends of the light-emitting diodes ED may be electrically connected to the second electrode CE.

The second element insulating layer QPAS2 may be disposed on the light-emitting diodes ED disposed between the first electrode AE and the second electrode CE. The second element insulating layer QPAS2 may be disposed at the center of the upper surface of the light-emitting diodes ED. The third element insulating layer QPAS3 may partially surround the outer surface of the light-emitting diodes ED. The third element insulating layer QPAS3 may protect the light-emitting diodes ED. The third element insulating layer QPAS3 may surround the outer surface of the light-emitting diodes ED.

The contact electrodes CTE may include first and second contact electrodes CTE1 and CTE2. The first contact electrode CTE1 may cover the first electrode branch AE2 and parts of the light-emitting diodes ED, and may electrically connect the first electrode branch AE2 with the light-emitting diodes ED. The second contact electrode CTE2 may cover the second electrode branch CE2 and other parts of the light emitting diodes ED, and may electrically connect the second electrode branch CE2 and the light emitting diodes ED.

The first contact electrode CTE1 may be disposed on the first electrode branch AE2 and extended in the second direction DR2. The first contact electrode CTE1 may contact first ends of the light-emitting diodes ED. The light-emitting diodes ED may be electrically connected to the first electrode AE through the first contact electrode CTE1.

The first contact electrode CTE1 may directly contact the upper surface of one end of the second element insulating layer QPAS2.

The second contact electrode CTE2 may be disposed on the second electrode branch CE2 and extended in the second direction DR2. The second contact electrode CTE2 may be spaced apart from the first contact electrodes CTE1 in the first direction DR1. The second contact electrode CTE2 may contact second ends of the light-emitting diodes ED. The light-emitting diodes ED may be electrically connected to the second electrode CE through the second contact electrode CTE2.

The second contact electrode CTE2 may directly contact the upper surface of the opposite end of the second element insulating layer QPAS2.

The first contact electrode CTE1 and the second contact electrode CTE2 may be formed on the same layer. Each of the first contact electrode CTE1 and the second contact electrode CTE2 may expose the upper surface of the center of the second element insulating layer QPAS2.

Each of the first contact electrode CTE1 and the second contact electrode CTE2 may include a conductive material. The first contact electrode CTE1 may include a first material, and the second contact electrode CTE2 may include a second material. It should be noted that the first material and the second material may have different physical properties. A more detailed description thereon will be given below.

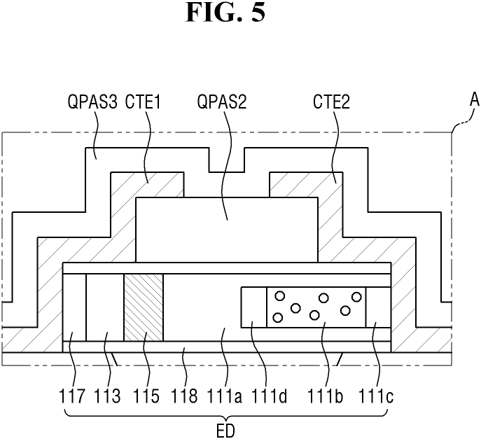

FIG. 5 is an enlarged view of area A of FIG. 4.

Referring to FIG. 5, the light-emitting diode ED may be a light-emitting diode. For example, the light-emitting diodes ED may have a size of a micro-meter or a nano-meter, and may be an inorganic light emitting diode containing an inorganic material. Inorganic light-emitting diodes may be aligned between two electrodes facing each other by an electric field formed in a particular direction between the two electrodes.

The light-emitting diode ED may have a shape extended in one direction. The light-emitting diode ED may have a shape of a rod, wire, tube, etc. The light-emitting diode ED may include first semiconductor layer 111a, 111b, 111c and 111d, a second semiconductor layer 113, an active layer 115, an electrode layer 117, and an insulating layer 118. The length of the light-emitting diode ED may be approximately 4 µm. In the following description, the width of the light-emitting diode ED and/or the components of the light-emitting diode ED may be measured in a direction from the first semiconductor layer toward the active layer 115. The thickness of the light-emitting diode ED and/or the components of the light-emitting diode ED may be measured in a direction perpendicular to the direction from the first semiconductor layer toward the active layer 115.

The first semiconductor layer 111a, 111b, 111c and 111d may be an n-type semiconductor. The first semiconductor layer 111 may include a semiconductor material having the following chemical formula: AlₓGa_{y}In_{1-x-y}N (0≤x≤1, 0≤y≤1, 0≤x+y≤1). For example, the first semiconductor layer 111 may be at least one of n-type doped AlGaInN, GaN, AlGaN, InGaN, AlN and InN. The first semiconductor layer 111 may be doped with an n-type dopant, and the n-type dopant may be Si, Ge, Sn, etc. For example, the first semiconductor layer 111 may be GaN doped with n-type Si. The thickness of the first semiconductor layers 111 may range, but is not limited to, from about 500 nm to about 1 µm.

The second semiconductor layer 113 may be p-type semiconductor, and may include a semiconductor material having the following chemical formula: AlₓGa_{y}In_{1-x-y}N (0≤x≤1, 0≤y≤1 and 0 ≤x+y≤1). For example, the second semiconductor layer 113 may be at least one of p-type doped AlGaInN, GaN, AlGaN, InGaN, AlN and InN. The second semiconductor layer 113 may be doped with a p-type dopant, and the p-type dopant may be Mg, Zn, Ca, Ba, etc. For example, the second semiconductor layer 113 may be GaN doped with p-type Mg. The second semiconductor layer 113 may have a width in the range of about 30 nm to about 200 nm, but is not limited thereto.

The active layer 115 may be disposed between the first semiconductor layer 111a, 111b, 111c and 111d, and the second semiconductor layer 113. The active layer 115 may emit light as electrons and holes are recombined therein in response to an emission signal applied through the first semiconductor layer 111a, 111b, 111c and 111d and the second semiconductor layer 113. The active layer 115 may include a material having a single or multiple quantum well structure. In case that the active layer 115 includes a material having a multiple quantum well structure, well layers and barrier layers may be alternately stacked each other in the structure. For example, the active layer 115 may have a structure in which a semiconductor material having a large band gap energy and a semiconductor material having a small band gap energy are alternately stacked each other, and may include Group III to Group V semiconductor materials depending on the wavelength range of the emitted light.

Although not shown in the drawings, a superlattice layer may be further disposed between the active layer 115 and the first semiconductor layer 111a, 111b, 111c and 111d. The superlattice layer may relieve stress due to a difference in lattice constants between the first semiconductor layer 111a, 111b, 111c and 111d and the active layer 115. For example, the superlattice layer may be made of InGaN or GaN. The width of the superlattice layer may range from approximately 50 nm to approximately 200 nm.

According to an embodiment, some of the light-emitting diodes ED of the display device 1 may include different active layers 115 to emit lights of different colors. For example, the active layer 115 of the light-emitting diode ED of the first light-emitting area LA1 may emit red light of a first color, the active layer 115 of the light-emitting diode ED of the second light-emitting area LA2 may emit green red light of a second color, and the active layer 115 of the light-emitting diode ED of the third light-emitting area LA3 may emit blue light of a third color. The light-emitting diode ED of the first light-emitting area LA1, the light-emitting diode ED of the second light-emitting area LA2 and the light-emitting diode ED of the third light-emitting emitting area LA3 may have different concentrations of dopants doped into the first semiconductor layer 111, the active layer 115 and the second semiconductor layer 113, or may have different values of x and y in the formula: AlₓGa_{y}In_{1-x-y}N (0 ≤x≤1,0 ≤y ≤1 and 0 ≤x+y ≤ 1).

For example, in case that the active layer 115 contains InGaN, the active layers 115 may emit lights of different colors depending on the content of indium (In). For example, as the content of indium (In) increases, the wavelength range of light output from the active layers 115 may move to the red wavelength range, and as the content of indium (In) decreases, the wavelength range of the output light may move to the blue wavelength range. Therefore, the content of indium (In) in the active layer 115 of the light-emitting diode ED of the first light-emitting area LA1 may be higher than the content of indium (In) in the active layer 115 of the light-emitting diode ED of each of the second light-emitting area LA2 and the third light-emitting area LA3. The content of indium (In) in the active layer 115 of the light-emitting diode ED of the second light-emitting area LA2 may be higher than the content of indium (In) in the active layer 115 of the light-emitting diode ED of the third light-emitting LA3.

For example, the content of indium (In) in the active layer 115 of the light-emitting diode ED of the third light-emitting area LA3 may be approximately 15%, the content of indium (In) in the active layer 115 of the light-emitting diode ED of the second light-emitting area LA2 may be approximately 25%, and the content of indium (In) in the active layer 115 of the light-emitting diode ED of the first light-emitting area LA1 may be approximately 35% or more. For example, by adjusting the content of indium (In) in the active layer 115, the light-emitting diodes ED may emit light of different colors.

According to the embodiment of the disclosure, the first semiconductor layer 111a, 111b, 111c and 111d may include a main semiconductor layer 111a, a nanoporous layer 111b inserted into the main semiconductor layer 111a, a one-side sub-semiconductor layer 111d between the nanoporous layer 111b and main semiconductor layer 111a, and an opposite-side sub-semiconductor layer 111c spaced apart from the one-side sub-semiconductor layer 111d with the nanoporous layer 111b therebetween.

The main semiconductor layer 111a may directly contact the upper surface of the one-side sub-semiconductor layer 111d, the upper surface of the nanoporous layer 111b, and the upper surface of the opposite-side sub-semiconductor layer 111c, and may directly contact the lower surface of the one-side sub-semiconductor layer 111d, the lower surface of the nanoporous layer 111b, and the lower surface of the opposite-side sub-semiconductor layer 111c. The end of the opposite-side sub-semiconductor layer 111c may be aligned with the end of the main semiconductor layer 111a in the thickness direction. The insulating layer 118 may cover and may directly contact the upper surface of the main semiconductor layer 111a, the upper surface of the active layer 115, the upper surface of the second semiconductor layer 113, and the upper surface of the electrode layer 117, and may cover and may directly contact the lower surface of the main semiconductor layer 111a, the lower surface of the active layer 115, the lower surface of the second semiconductor layer 113, and the lower surface of the electrode layer 117.

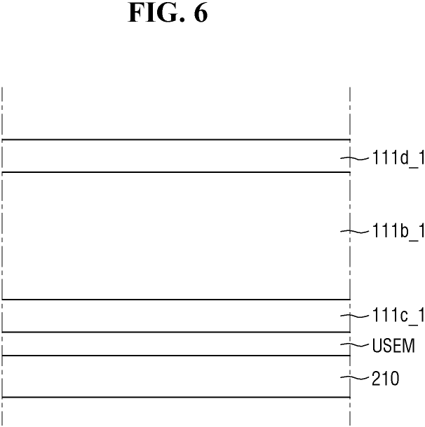

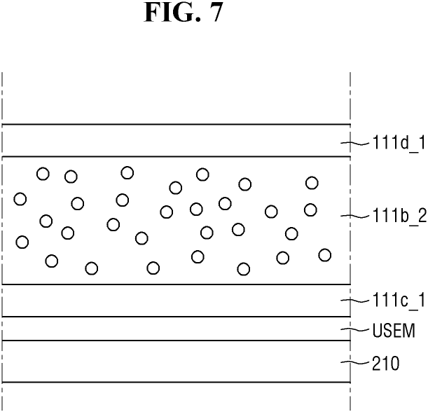

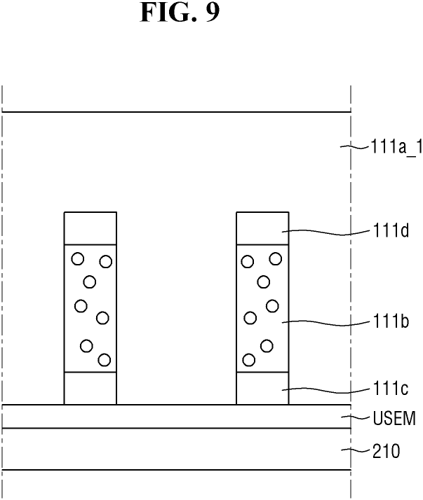

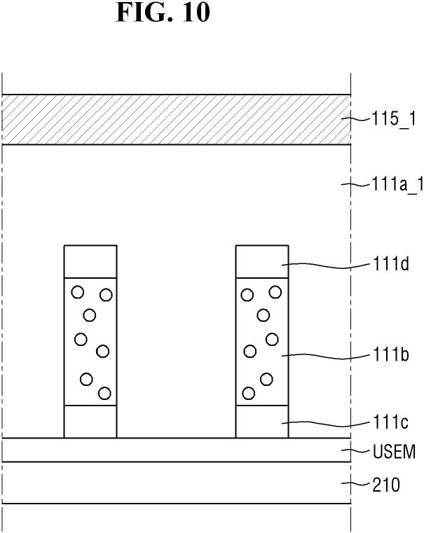

The n-type Si doping concentration of the main semiconductor layer 111a may be greater than the n-type Si doping concentration of the one-side sub-semiconductor layer 111d and the n-type Si doping concentration of the opposite-side sub-semiconductor layer 111c. The nanoporous layer 111b may include GaN doped with n-type Si including a porous material. For example, the concentration of the porous material of the nanoporous layer 111b may be greater than the concentration of the porous material of the main semiconductor layer 111a, the concentration of the porous material of the first one-side sub-semiconductor layer 111d, and the concentration of the porous material of the opposite-side sub-semiconductor layer 111c. According to an embodiment of the disclosure, the first semiconductor layer may relieve strain of the active layer 115 by further disposing the nanoporous layer 111b containing a porous material. It should be noted that the contact resistance between the nanoporous layer 111b and the second contact electrode CTE2 (n-contact) may be greater than the contact resistance between the main semiconductor layer 111a and the second contact electrode CTE2 (n-contact). Accordingly, the total contact loss of the light-emitting diode ED may occur, resulting in current leakage. The display device according to the embodiment of the disclosure may be designed such that the nanoporous layer 111b is inserted into the main semiconductor layer 111a, and the end of the opposite-side sub-semiconductor layer 111c and the end of the main semiconductor layer 111a contact the second contact electrode CTE2 together. In this manner, it is possible to prevent the total contact loss of the light-emitting diode ED and leakage of current. As described above, the n-type Si doping concentration of the main semiconductor layer 111a may be greater than the n-type Si doping concentration of the one-side sub-semiconductor layer 111d and the n-type Si doping concentration of the opposite-side sub-semiconductor layer 111c. As will be described later with the method of fabricating the display device, when an electro-chemical (EC) etching process is performed on the intermediate semiconductor layer 111b_1 to form the nanoporous layer 111b_2 having a porous material, the one-side sub-semiconductor layer 111d having a low n-type Si doping concentration hardly reacts during the electro-chemical (EC) etching process, such that a porous material may not be formed, as shown in FIGS. 6 and 7. Accordingly, as shown in FIG. 9, in the process of re-growing (or forming) the main semiconductor layer 111a_1, the roughness of the surface of the main semiconductor layer 111a_1 (the surface facing an active layer 115_1 in FIG. 10) may be significantly reduced, facilitating the growth of the active layer 115_1.

Hereinafter, a method of fabricating a display device according to an embodiment of the disclosure will be described. In the following description, the same or similar elements will be denoted by the same or similar reference numerals, and redundant descriptions will be omitted or briefly described.

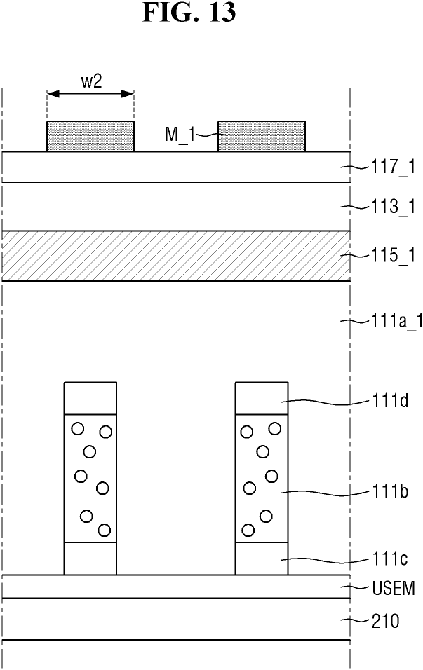

FIGS. 6 to 16 are schematic cross-sectional views showing processing steps of a method of fabricating a display device according to an embodiment of the disclosure. A method of fabricating a display device will be described with reference to FIGS. 6 to 11 in conjunction with FIGS. 1 to 5.

A method of fabricating a display device according to an embodiment may include preparing a substrate where first banks BNK1 spaced apart from one another are disposed.

The method may include forming a first electrode AE and a second electrode CE that are disposed on the first banks BNK1 to cover the first banks BNK1 and are spaced apart from each other.

The method may include forming a first element insulating layer QPAS1 on the first electrode AE and the second electrode CE.

The method may include disposing a light-emitting diode ED between the first electrode AE and the second electrode CE on the first element insulating layer QPAS1.

The disposing the light-emitting element may include forming the light-emitting diode ED and disposing the light-emitting diode ED between the first electrode AE and the second electrode CE.

The forming the light-emitting diode ED may include forming an undoped semiconductor layer on a substrate; forming an intermediate semiconductor layer containing GaN doped with n-type Si on the undoped semiconductor layer; forming a first sub-semiconductor layer containing GaN doped with n-type Si on the intermediate semiconductor layer; forming a nanoporous layer by electrochemically etching the intermediate semiconductor layer; etching the nanoporous layer and the first sub-semiconductor layer by placing a hard mask on the first sub-semiconductor layer; forming a main semiconductor layer on a side surface of the nanoporous layer and a side surface of the first sub-semiconductor layer; removing the hard mask and re-growing the main semiconductor layer; forming an active layer on the main semiconductor layer; forming a second semiconductor layer containing GaN doped with p-type Si on the active layer; forming an electrode layer on the second semiconductor layer; and etching the electrode layer, the second semiconductor layer, the active layer, and the main semiconductor layer using a mask on the electrode layer.

Initially, as shown in FIG. 6, the forming the light-emitting diode ED may include forming an undoped semiconductor layer USEM on a substrate 210; forming a first sub-semiconductor layer 111c_1 containing GaN doped with n-type Si on the undoped semiconductor layer USEM; forming an intermediate semiconductor layer 111b_1 containing GaN doped with n-type Si on the first sub-semiconductor layer 111c_1; and forming a second sub-semiconductor layer 111d_1 containing GaN doped with n-type Si on the intermediate semiconductor layer 111b_1. The first sub-semiconductor layer 111c_1 and the opposite-side sub-semiconductor layer 111c of FIG. 5 may include the same material, and the second sub-semiconductor layer 111d_1 and the one-side sub-semiconductor layer 111d of FIG. 5 may include the same material. The Si doping concentration of each of the first and second sub-semiconductor layers 111c_1 and 111d_1 may be lower than the Si doping concentration of the intermediate semiconductor layer 111b_1.

The intermediate semiconductor layer 111b_1 may be electrochemically etched to form a nanoporous layer 111b_2. The nanoporous layer 111b_2 may include GaN doped with n-type Si including a porous material. For example, the concentration of the porous material in the nanoporous layer 111b_2 may be greater than the concentration of the porous material in each of the first and second sub-semiconductor layers 111c_1 and 111d_1. According to an embodiment of the disclosure, in order to perform the electrochemical etching process, potassium hydroxide (KOH) or nitric acid (HNO₃) solution may be used, but the disclosure is not limited thereto.

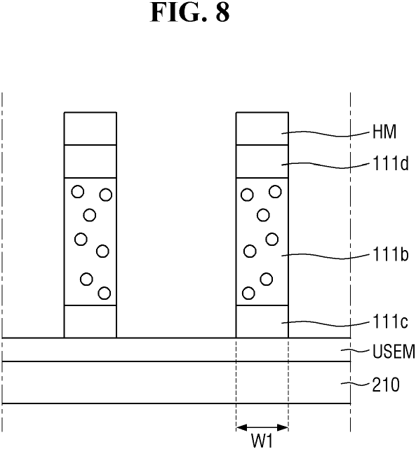

Referring to FIG. 8, a hard mask HM may be placed on the second sub-semiconductor layer 111d_1 (see FIG. 7), and the second sub-semiconductor layer 111d-1, the nanoporous layer 111b_2 and the first sub-semiconductor layer 111c-1 may be etched. The hard mask HM may include an inorganic insulating material. For example, the inorganic insulating material may include, but is not limited to, silicon oxide (SiO₂) or silicon nitride (SiNx). The second sub-semiconductor layer 111d_1, the nanoporous layer 111b_2, and the first sub-semiconductor layer 111c_1 may be etched, such that the second one-side sub-semiconductor layer 111d, the nanoporous layer 111b, and the first opposite-side sub-semiconductor layer 111c shown in FIG. 8 are formed. The second one-side sub-semiconductor layer 111d, the nanoporous layer 111b, and the first opposite-side sub-semiconductor layer 111c may have the same width W1.

As shown in FIG. 9, a main semiconductor layer 111a_1 may be formed on the side surface of the first opposite-side sub-semiconductor layer 111c, the side surface of the nanoporous layer 111b, and the side surface of the opposite-side sub-semiconductor layer 111c, the hard mask HM may be removed, and the main semiconductor layer 111a_1 may be re-grown. In the forming the main semiconductor layer on the side surface of the first sub-semiconductor layer 111c, the side surface of the nano-porous layer 111b, and the side surface of the second sub-semiconductor layer 111c, the main semiconductor layer 111a_1 may be grown to the same height as the surface of the second sub-semiconductor layer 111d. By removing the hard mask HM and re-growing the main semiconductor layer 111a_1, the main semiconductor layer 111a_1 covering the upper surface of the second sub-semiconductor layer 111c may be formed as shown in FIG. 9.

The material of the main semiconductor layer 111a_1 has been described above with reference to FIG. 5; and, therefore, the redundant descriptions will be omitted.

As shown in FIG. 10, an active layer 115_1 may be formed on the re-grown main semiconductor layer 111a_1. The active layer 115_1 and the active layer 115 of FIG. 5 may contain the same material; and, therefore, the redundant descriptions will be omitted.

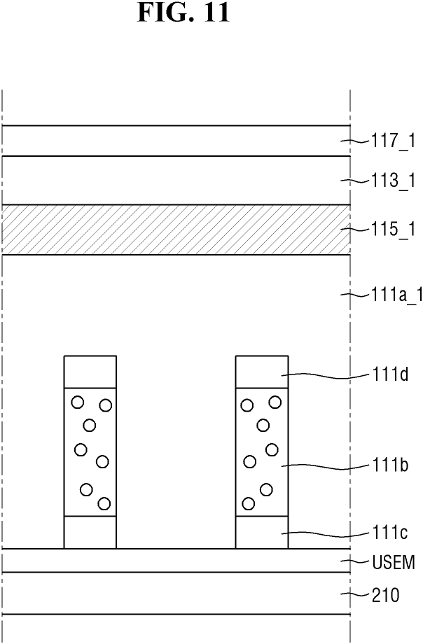

As shown in FIG. 11, a second semiconductor layer 113_1 containing GaN doped with p-type Si may be formed on the active layer 115_1. The second semiconductor layer 113_1 and the second semiconductor layer 113 of FIG. 5 may contain the same material; and, therefore, the redundant descriptions will be omitted.

As shown in FIG. 11, an electrode layer 117_1 may be formed on the second semiconductor layer 113_1.

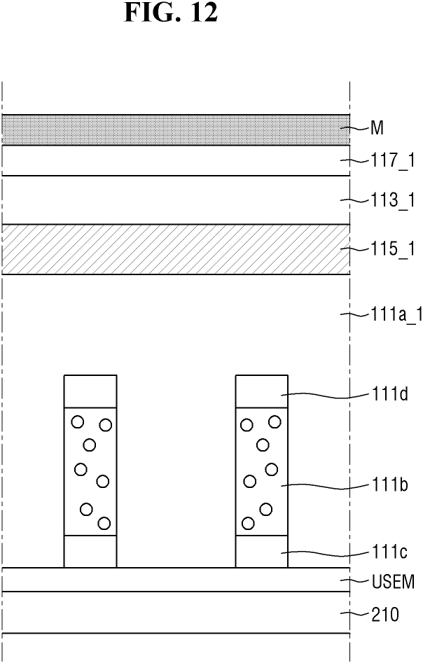

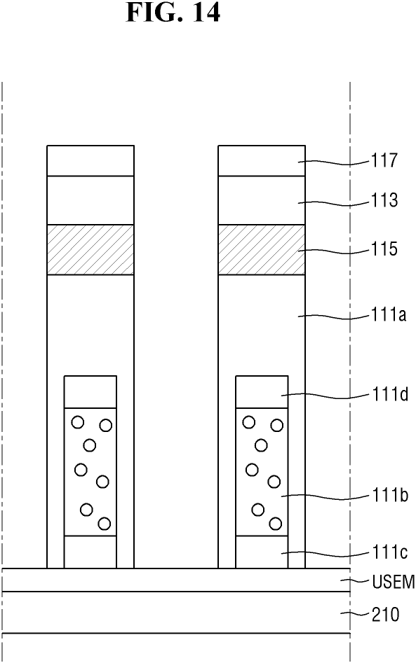

As shown in FIGS. 12 to 14, the electrode layer 117_1, the second semiconductor layer 113_1, the active layer 115_1 and the main semiconductor layer 111a_1 may be etched using a mask M on the electrode layer 117_1. Initially, the mask M may be placed on the electrode layer 117_1 as shown in FIG. 12. The mask M may include an inorganic insulating material. For example, the inorganic insulating material may include, but is not limited to, silicon oxide (SiO₂) or silicon nitride (SiNx). The mask M_1 may be patterned. The width W2 of the patterned mask M_1 may be larger than the width W1 of the sub-semiconductor layers 111c and 111d of FIG. 8. The patterned mask M_1 may overlap the sub-semiconductor layers 111c and 111d and the nanoporous layer 111b in the thickness direction. FIG. 14 shows the electrode layer 117, the second semiconductor layer 113, the active layer 115 and the main semiconductor layer 111a after being etched using the mask M_1. Subsequently, the mask M_1 may be removed.

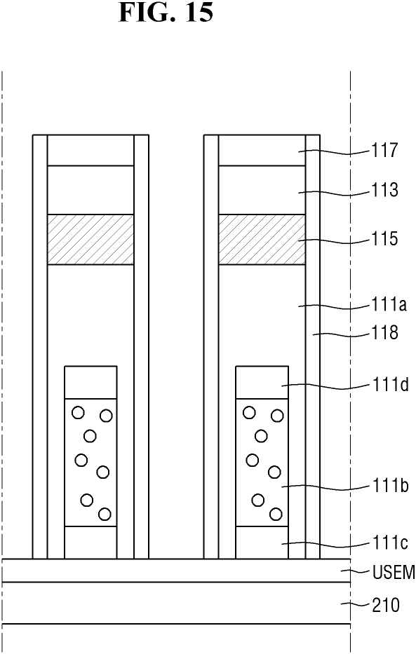

As shown in FIG. 15, an insulating layer 118 may be formed to cover the side surface of the active layer 115, the side surface of the main semiconductor layer 111a, the side surface of the second semiconductor layer 113, and the side surface of the electrode layer 117. The insulating layer 118 may include an inorganic insulating material. For example, the inorganic insulating material may include, but is not limited to, silicon oxide (SiO₂) or silicon nitride (SiNx).

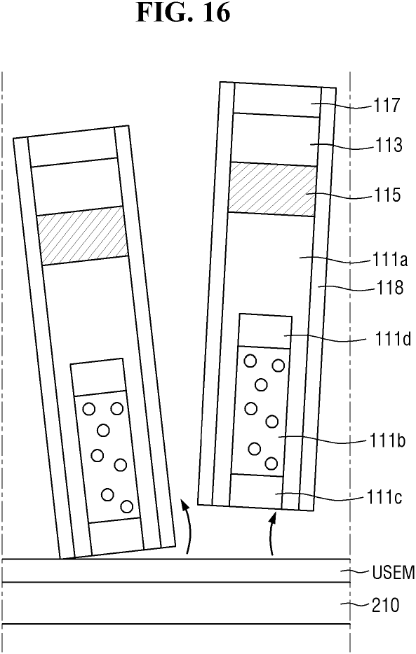

As shown in FIG. 16, the light-emitting elements thus fabricated may be separated from the undoped semiconductor layer USEM. After the light-emitting elements have been separated, they may be disposed between the first electrode AE and the second electrode CE (see FIG. 5).

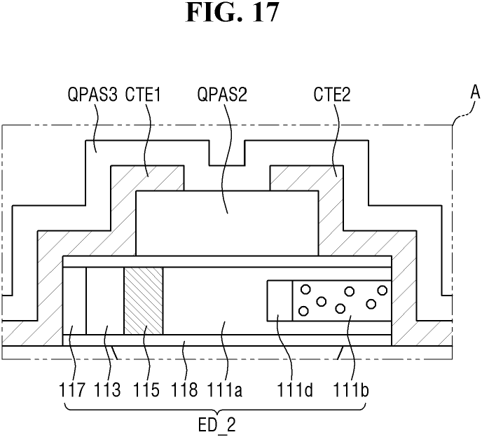

FIG. 17 is a schematic cross-sectional view showing a light-emitting element in a display device according to another embodiment.

A light-emitting diode ED_1 according to the embodiment of FIG. 17 is different from the light-emitting diode ED according to the embodiment of FIG. 5 in that the opposite-side sub-semiconductor layer 111c (see FIG. 5) is omitted. For example, the end of the nanoporous layer 111b may be aligned with the end of the main semiconductor layer 111a in the thickness direction. The end of the nanoporous layer 111b and the end of the main semiconductor layer 111a may contact the second contact electrode CTE2.

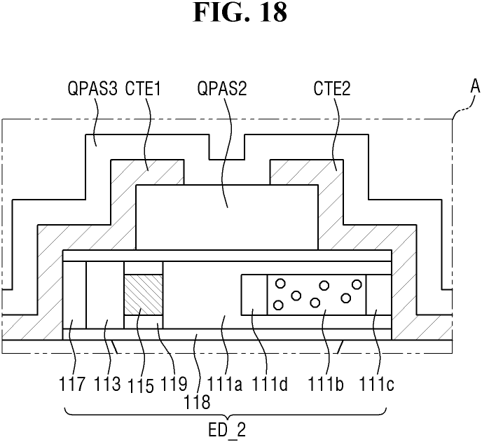

FIG. 18 is a schematic cross-sectional view showing a light-emitting element in a display device according to yet another embodiment.

A light-emitting diode ED_2 according to the embodiment of FIG. 18 is different from the light-emitting diode ED according to the embodiment of FIG. 5 in that the former further includes a second insulating layer 119 disposed on and under the active layer 115. The second insulating layer 119 may include an inorganic insulating material. For example, the inorganic insulating material may include, but is not limited to, silicon oxide (SiO₂) or silicon nitride (SiNx). The second insulating layer 119 may contact the adjacent main semiconductor layer 111a and the second semiconductor layer 113. For example, the thickness of the active layer 115 may be smaller than that of the adjacent main semiconductor layer 111a, and the second insulating layer 119 may be disposed on the side surface of the main semiconductor layer 111a exposed by the active layer 115.

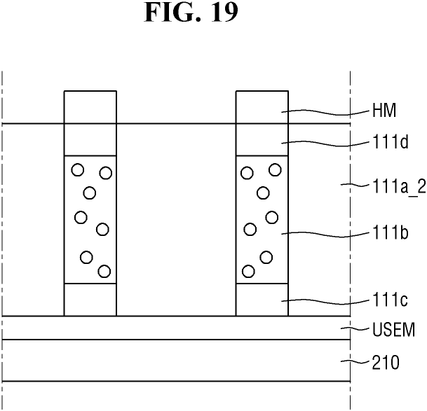

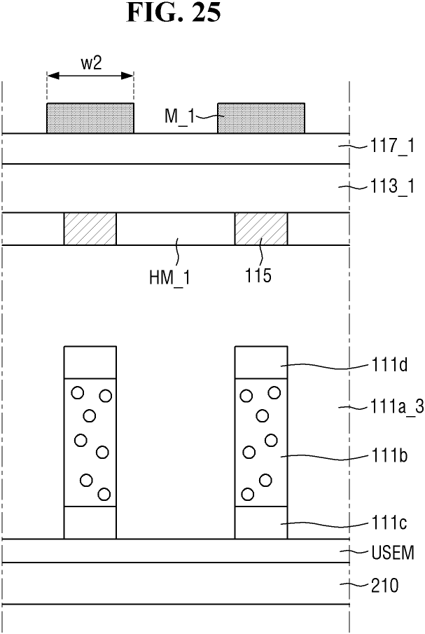

FIGS. 19 to 27 are schematic cross-sectional views showing processing steps of a method of fabricating a display device according to yet another embodiment of the disclosure. FIGS. 19 to 27 are schematic cross-sectional views showing processing steps of fabricating a light-emitting diode ED_2 of the display device according to the embodiment of FIG. 18.

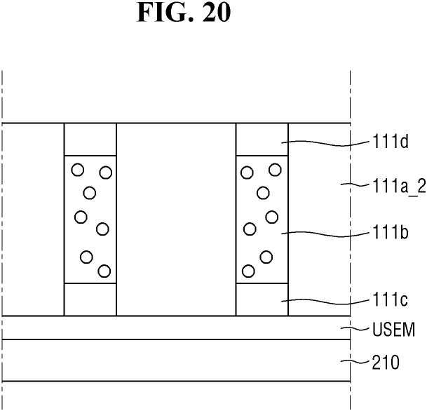

Referring to FIGS. 19 and 20, a main semiconductor layer 111a_2 may be formed on the side surface of the first sub-semiconductor layer 111c, the side surface of the nano-porous layer 111b, and the side surface of the second sub-semiconductor layer 111c, the hard mask HM may be removed, and the main semiconductor layer 111a_2 may be re-grown. The main semiconductor layer 111a_3 may be re-grown to cover the upper surface of the second sub-semiconductor layer 111c.

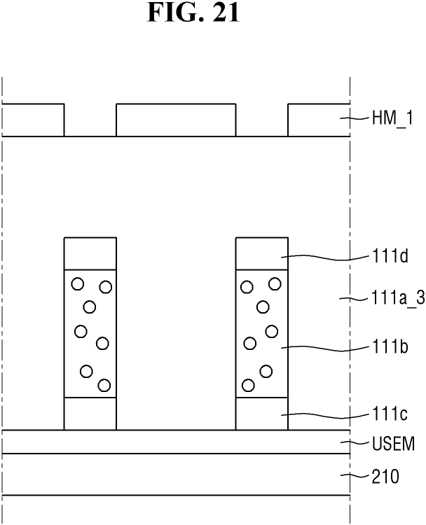

Referring to FIG. 21, a second hard mask HM_1 including a through hole may be placed on the main semiconductor layer 111a_3. The through hole may overlap the sub-semiconductor layers 111c and 111d and the nanoporous layer 111b in the thickness direction. The second hard mask HM_1 may include an inorganic insulating material. For example, the inorganic insulating material may include, but is not limited to, silicon oxide (SiO₂) or silicon nitride (SiNx).

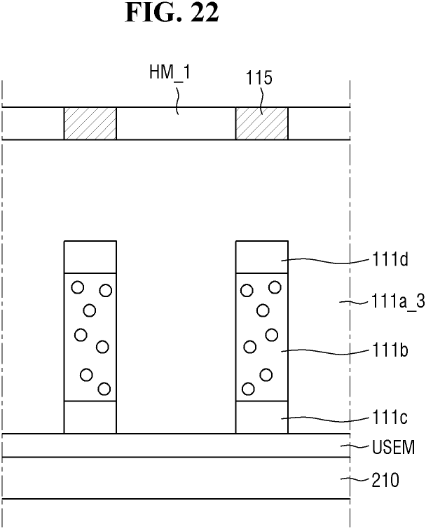

Referring to FIG. 22, an active layer 115 may be formed in the through hole.

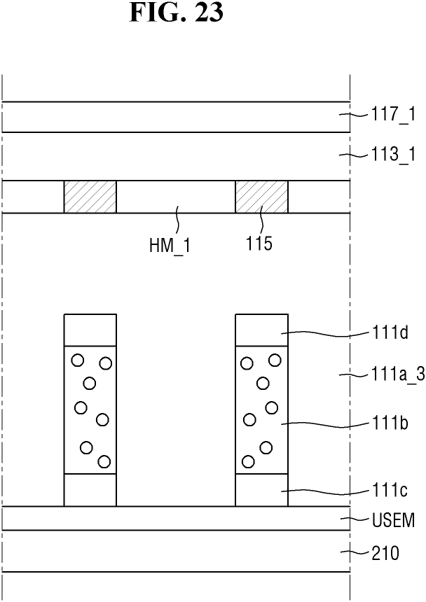

Referring to FIG. 23, a second semiconductor layer 113_1 containing GaN doped with p-type Si may be formed on an active layer 115_1, and an electrode layer 117_1 may be formed on the second semiconductor layer 113_1.

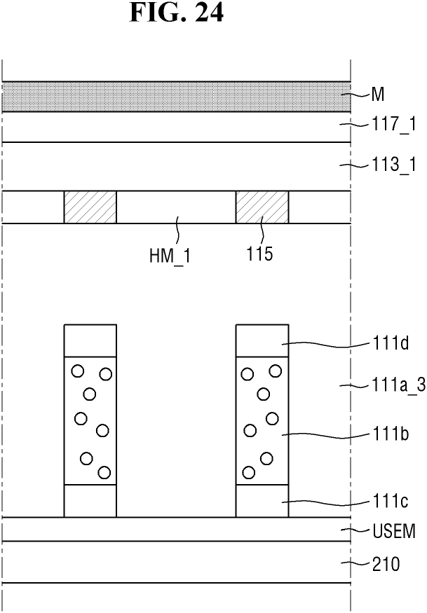

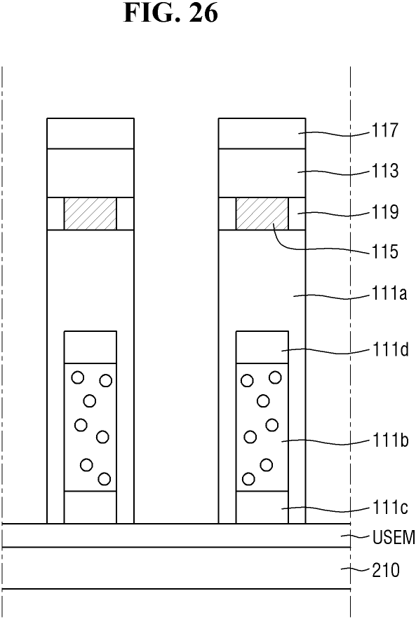

As shown in FIGS. 24 to 26, the electrode layer 117_1, the second semiconductor layer 113_1, the second hard mask HM_1, and the main semiconductor layer 111a_1 may be etched using a mask M on the electrode layer 117_1. Initially, the mask M may be placed on the electrode layer 117_1 as shown in FIG. 24. The mask M may include an inorganic insulating material. For example, the inorganic insulating material may include, but is not limited to, silicon oxide (SiO₂) or silicon nitride (SiNx). The mask M_1 may be patterned. The width W2 of the patterned mask M_1 may be larger than the width of the sub-semiconductor layers 111c and 111d. The patterned mask M_1 may overlap the sub-semiconductor layers 111c and 111d and the nanoporous layer 111b in the thickness direction. FIG. 26 shows the electrode layer 117, the second semiconductor layer 113, the second insulating layer 119, and the main semiconductor layer 111a after being etched using the mask M_1. Subsequently, the mask M_1 may be removed. Since the etching process is carried out after the second hard mask HM_1 is placed on the side surface of the active layer 115, it is possible to prevent damage to the active layer 115.

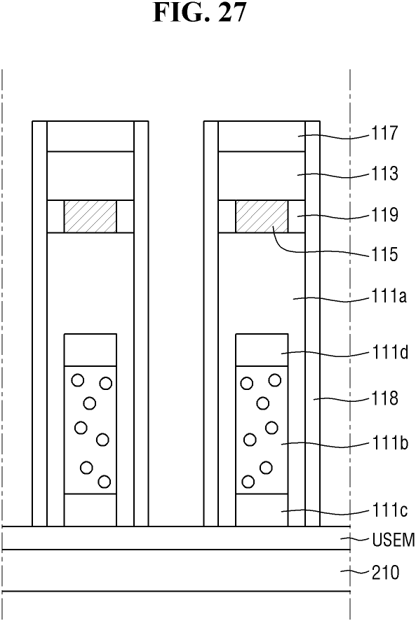

As shown in FIG. 27, an insulating layer 118 may be formed on the side surface of the main semiconductor layer 111a, the side surface of the second insulating layer 119, the side surface of the second semiconductor layer 113, and the side surface of the electrode layer 117. The insulating layer 118 may directly contact the side surface of the main semiconductor layer 111a, the side surface of the second insulating layer 119, the side surface of the second semiconductor layer 113, and the side surface of the electrode layer 117.

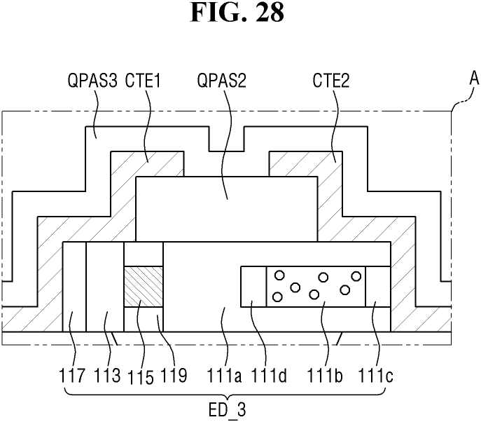

FIG. 28 is a schematic cross-sectional view showing a light-emitting element in a display device according to yet another embodiment.

A light-emitting diode ED_3 according to the embodiment of FIG. 28 is different from the light-emitting diode ED_2 according to the embodiment of FIG. 18 in that the insulating layer 118 is omitted. Unlike the light-emitting diode ED_2 of FIG. 18, the second contact electrode CTE2 may further contact the upper surface of the main semiconductor layer 111a, and the first contact electrode CTE1 may further contact the upper surface of the electrode layer 117 and the upper surface of the second semiconductor layer 113.

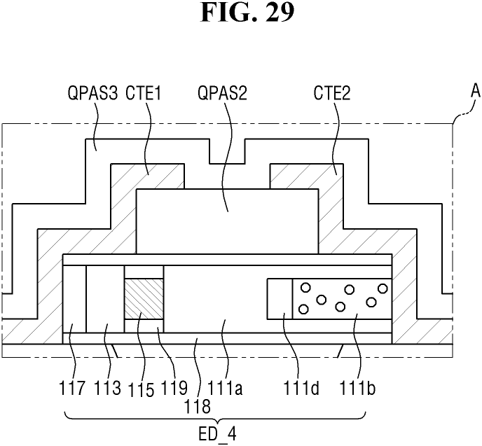

FIG. 29 is a schematic cross-sectional view showing a light-emitting element in a display device according to yet another embodiment.

A light-emitting diode ED_4 according to the embodiment of FIG. 29 is different from the light-emitting diode ED_2 according to the embodiment of FIG. 18 in that the opposite-side sub-semiconductor layer 111c (see FIG. 18) is omitted. For example, the end of the nanoporous layer 111b may be aligned with the end of the main semiconductor layer 111a in the thickness direction. The end of the nanoporous layer 111b and the end of the main semiconductor layer 111a may contact the second contact electrode CTE2.

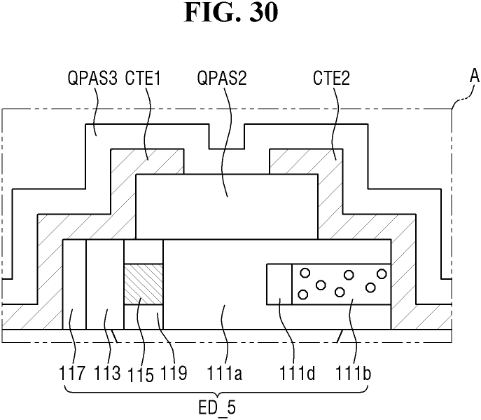

FIG. 30 is a schematic cross-sectional view showing a light-emitting element in a display device according to yet another embodiment.

A light-emitting diode ED_5 according to the embodiment of FIG. 30 is different from the light-emitting diode ED_3 according to the embodiment of FIG. 28 in that the opposite-side sub-semiconductor layer 111c (see FIG. 28) is omitted. For example, the end of the nanoporous layer 111b may be aligned with the end of the main semiconductor layer 111a in the thickness direction. The end of the nanoporous layer 111b and the end of the main semiconductor layer 111a may contact the second contact electrode CTE2.

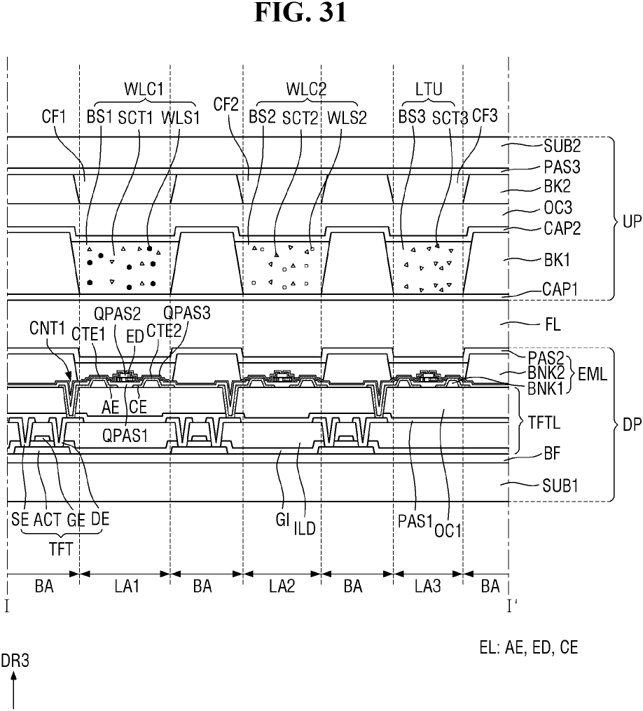

FIG. 31 is a schematic cross-sectional view of a display device according to yet another embodiment of the disclosure.

A display device according to the embodiment of FIG. 31 is different from the display device according to the embodiment of FIG. 2 in that the former includes a first substrate part DP, a second substrate part UP facing the first substrate part DP, and a filling layer FL between the two substrate parts DP and UP.

The first substrate part DP may include a first substrate SUB1, a buffer layer BF, a thin-film transistor layer TFTL, and an emission layer EML. The second substrate part UP may include a first capping layer CAP1, a first light-blocking member BK1, a first wavelength converting part WLC1, a second wavelength converting part WLC2, a light transmitting part LTU, a second capping layer CAP2, a third planarization layer OC3, a second light-blocking member BK2, first to third color filters CF1, CF2 and CF3, a third passivation layer PAS3, and a second substrate SUB2. The first substrate part DP may include a thin-film transistor including a thin-film transistor layer TFTL, and the second substrate part UP may include a color filter including color filters CF1, CF2 and CF3.

In embodiments, the filling layer FL may be made of a material that can transmit light. In embodiments, the filling layer FL may be made of an organic material. For example, the filling layer FL may be made of a silicon-based organic material, an epoxy-based organic material, or a mixture of a silicon-based organic material, an epoxy-based organic material, etc.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display device comprising:
first banks spaced apart from one another and disposed on a substrate;
a first electrode and a second electrode disposed on the respective first banks to cover the respective first banks, the first electrode and the second electrode being spaced apart from each other; and
a light-emitting element disposed between the first electrode and the second electrode, wherein
the light-emitting element comprises:
an active layer;
a first semiconductor layer; and
a second semiconductor layer disposed between the active layer and the first electrode, and
the first semiconductor layer comprises:
a main semiconductor layer; and
a nanoporous layer disposed in the main semiconductor layer.

2. The display device of claim 1, wherein the main semiconductor layer directly contacts an outer surface of the nanoporous layer.

3. The display device of claim 2, wherein the main semiconductor layer includes GaN doped with n-type Si.

4. The display device of claim 3, wherein the second semiconductor layer includes GaN doped with p-type Si.

5. The display device of claim 4, wherein the first semiconductor layer further comprises a one-side sub-semiconductor layer between the nanoporous layer and the main semiconductor layer.

6. The display device of claim 5, wherein the one-side sub-semiconductor layer includes GaN doped with n-type Si.

7. The display device of claim 6, wherein an n-type Si doping concentration of the main semiconductor layer is greater than an n-type Si doping concentration of the one-side sub-semiconductor layer.

8. The display device of claim 7, wherein an end of the light-emitting element is aligned with an end of the main semiconductor layer and an end of the nanoporous layer.

9. The display device of claim 7, wherein the first semiconductor layer further comprises an opposite-side sub-semiconductor layer spaced apart from the one-side sub-semiconductor layer with the nanoporous layer therebetween.

10. The display device of claim 9, wherein the opposite-side sub-semiconductor layer includes GaN doped with n-type Si.

11. The display device of claim 10, wherein the n-type Si doping concentration of the main semiconductor layer is greater than an n-type Si doping concentration of the opposite-side sub-semiconductor layer.

12. The display device of claim 11, wherein the light-emitting element further comprises an insulating layer covering an outer surface of the active layer, an outer surface of the main semiconductor layer, and an outer surface of the second semiconductor layer.

13. The display device of claim 11, wherein
a thickness of the active layer is smaller than a thickness of the main semiconductor layer in a lateral direction, and
the light-emitting element further comprises an insulating layer disposed between the main semiconductor layer and the second semiconductor layer.

14. The display device of claim 13, wherein the insulating layer contacts an outer surface of the active layer.

15. The display device of claim 11, wherein
a thickness of the active layer is smaller than a thickness of the main semiconductor layer in a lateral direction, and
the light-emitting element further comprises:
a first insulating layer disposed on an outer surface of the active layer; and
a second insulating layer covering an outer surface of the active layer, an outer surface of the main semiconductor layer, and an outer surface of the second semiconductor layer.

16. A method of fabricating a display device, the method comprising:
forming an undoped semiconductor layer on a substrate;
forming an intermediate semiconductor layer including GaN doped with n-type Si on the undoped semiconductor layer;
forming a first sub-semiconductor layer including GaN doped with n-type Si on the intermediate semiconductor layer;
forming a nanoporous layer by electrochemically etching the intermediate semiconductor layer;
etching the nanoporous layer and the first sub-semiconductor layer after placing a hard mask on the first sub-semiconductor layer;
growing a main semiconductor layer on a side surface of the nanoporous layer and a side surface of the first sub-semiconductor layer;
removing the hard mask;
re-growing the main semiconductor layer;
forming an active layer on the main semiconductor layer;
forming a second semiconductor layer including GaN doped with p-type Si on the active layer;
forming an electrode layer on the second semiconductor layer; and
etching the electrode layer, the second semiconductor layer, the active layer, and the main semiconductor layer using a mask on the electrode layer.

17. The method of claim 16, wherein
the main semiconductor layer includes GaN doped with n-type Si, and
an n-type Si doping concentration of the main semiconductor layer is greater than an n-type Si doping concentration of the first sub-semiconductor layer.

18. The method of claim 16, wherein
after the etching of the electrode layer, the second semiconductor layer, the active layer, and the main semiconductor layer using the mask on the electrode layer, the method further comprises:
forming an insulating layer covering a side surface of the active layer, a side surface of the main semiconductor layer, and a side surface of the second semiconductor layer.

19. The method of claim 16, further comprising:
forming a second sub-semiconductor layer including GaN doped with n-type Si on the undoped semiconductor layer, between the forming of the undoped semiconductor layer on the substrate and the forming of the intermediate semiconductor layer including GaN doped with n-type Si on the undoped semiconductor layer, wherein
the etching of the nanoporous layer and the first sub-semiconductor layer after placing a hard mask on the first sub-semiconductor layer comprises etching the second sub-semiconductor layer, and
the main semiconductor layer is further formed on a side surface of the second sub-semiconductor layer.

20. A method of fabricating a display device, the method comprising:
forming an undoped semiconductor layer on a substrate;
forming an intermediate semiconductor layer including GaN doped with n-type Si on the undoped semiconductor layer;
forming a first sub-semiconductor layer including GaN doped with n-type Si on the intermediate semiconductor layer;
forming a nanoporous layer by electrochemically etching the intermediate semiconductor layer;
etching the nanoporous layer and the first sub-semiconductor layer after disposing a first hard mask on the first sub-semiconductor layer;
growing a main semiconductor layer on a side surface of the nanoporous layer and a side surface of the first sub-semiconductor layer;
removing the first hard mask;
re-growing the main semiconductor layer;
disposing a second hard mask comprising a through hole on the re-grown main semiconductor layer;
forming an active layer on the re-grown main semiconductor layer in the through hole of the second hard mask;
forming a second semiconductor layer including GaN doped with p-type Si on the second hard mask and the active layer;
forming an electrode layer on the second semiconductor layer; and
etching the electrode layer, the second hard mask, the second semiconductor layer, and the main semiconductor layer using a mask on the electrode layer.
